(19) United States
(12) Patent Application Publication
(10) Pub. No.: US 2012/0072148 A1
(43) Pub. Date: Mar. 22, 2012

(54) VOLTAGE DROP ANALYSIS APPARATUS, VOLTAGE DROP ANALYSIS METHOD, AND SYSTEM

(75) Inventor: Tomoyuki Yoda, Kawasaki-Shi (JP)

(73) Assignee: KABUSHIKI KAISHA TOSHIBA, Tokyo (JP)

(21) Appl. No.: 13/027,050

(22) Filed: Feb. 14, 2011

(30) Foreign Application Priority Data
Sep. 16, 2010 (JP) 2010-208191

(51) Int. Cl. G06F 19/00; G01R 19/00

(52) U.S. Cl. 702/64

(57) ABSTRACT

A current analysis unit of a voltage drop analysis apparatus analyzes currents flowing through the element, and outputs current information concerning currents flowing through the element. A voltage drop analysis unit analyzes voltage drops of the element on the basis of the current information and circuit layout information including information concerning connection of the element, arrangement of the element and power supply interconnection connected to the element, and outputs voltage drop information concerning voltage drops of the element. A corner selection unit selects corner information of the element from a corner information list containing a plurality of pieces of corner information. A voltage drop correction unit which outputs post correction voltage drop information obtained by correcting the voltage drop information on the basis of the voltage drop information, the selected corner information, and the voltage drop correction information prescribing relations between the corner information and correction quantities of the voltage drop information.

### CROSS-REFERENCE TO RELATED APPLICATION

This application is based upon and claims the benefit of priority from the prior Japanese Patent Application No. 2010-208191, filed on Sep. 16, 2010, the entire contents of which are incorporated herein by reference.

### BACKGROUND

1. Field

Embodiments described herein relate generally to a voltage drop analysis apparatus which executes voltage drop analysis on a semiconductor integrated circuit, and a voltage drop analysis method.

2. Background Art

In recent years, size shrinking and speed increase of semiconductor integrated circuits have been promoted. As a result, false operations of a circuit caused by a voltage drop in a chip have posed serious problems.

A voltage drop analysis technique and a timing analysis technique taking a voltage drop analysis result into consideration are very important to prevent false operations of the circuit caused by voltage drops.

On the other hand, process variations caused by size shrinking has become larger, and consequently the number of corner information pieces to be subjected to the timing analysis has increased.

In addition, the voltage drop analysis also needs to be conducted every corner information. As a result, the number of corners to be subjected to the voltage drop analysis has increased, and execution time of the voltage drop analysis has posed a serious problem.

### BRIEF DESCRIPTION OF THE DRAWINGS

FIG. 1 is a diagram showing an example of a configuration of a system 1000 including a voltage drop analysis apparatus 100 according to an embodiment of the present invention;

FIG. 2 is a circuit diagram showing an example of a circuit configuration of an element subject to voltage drop analysis made by the voltage drop analysis apparatus 100 shown in FIG. 1;

FIG. 3 is a diagram showing an example of the voltage drop correction information corresponding to a parameter (temperature) included in the corner information;

FIG. 4 is a diagram showing an example of the voltage drop correction information corresponding to a parameter (voltage) included in the corner information;

FIG. 5 is a diagram showing an example of the voltage drop correction information corresponding to a parameter (transistor process) included in the corner information;

FIG. 6 is a diagram showing an example of the voltage drop correction information corresponding to a parameter (interconnection process) included in the corner information;

FIG. 7 is a diagram showing an example of a concept of the voltage drop correction information concerning the leak current;

FIG. 8 is a diagram showing an example of a concept of the voltage drop correction information concerning the through current;

FIG. 9 is a diagram showing an example of a concept of the voltage drop correction information concerning the charge and discharge current; and

FIG. 10 is a flow chart showing an example of the operation of the voltage drop analysis of an element of analysis object conducted in the voltage drop analysis apparatus 100 shown in FIG. 1.

### DETAILED DESCRIPTION

A voltage drop analysis apparatus, according to an embodiment, analyzes voltage drops of an element included in a semiconductor integrated circuit. The voltage drop analysis apparatus comprises a current analysis unit which analyzes currents flowing through the element on the basis of operation scenario information which prescribes transitions of an input signal and an output signal of the element, input signal transition time information which prescribes the transition time of the input signal of the element, signal interconnection load information which prescribes resistance values and capacitance values of signal interconnections connected to the element, and cell current dissipation information which prescribes relations among the operation scenario information, the input signal transition time information, the signal interconnection load information, and currents flowing through the element, and which outputs current information concerning currents flowing through the element. The voltage drop analysis apparatus comprises a voltage drop analysis unit which analyzes voltage drops of the element on the basis of the current information and circuit layout information including information concerning connection of the element, arrangement of the element and power supply interconnection connected to the element, and which outputs voltage drop information concerning voltage drops of the element. The voltage drop analysis apparatus comprises a corner selection unit which selects corner information of the element from a corner information list containing a plurality of pieces of corner information. The voltage drop analysis apparatus comprises a voltage drop correction unit which outputs post correction voltage drop information obtained by correcting the voltage drop information on the basis of the voltage drop information, the selected corner information, and the voltage drop correction information prescribing relations between the corner information and correction quantities of the voltage drop information.

Hereafter, a voltage drop analysis apparatus and a voltage drop analysis method according to the present invention will be described more specifically with reference to the drawings.

### First Embodiment

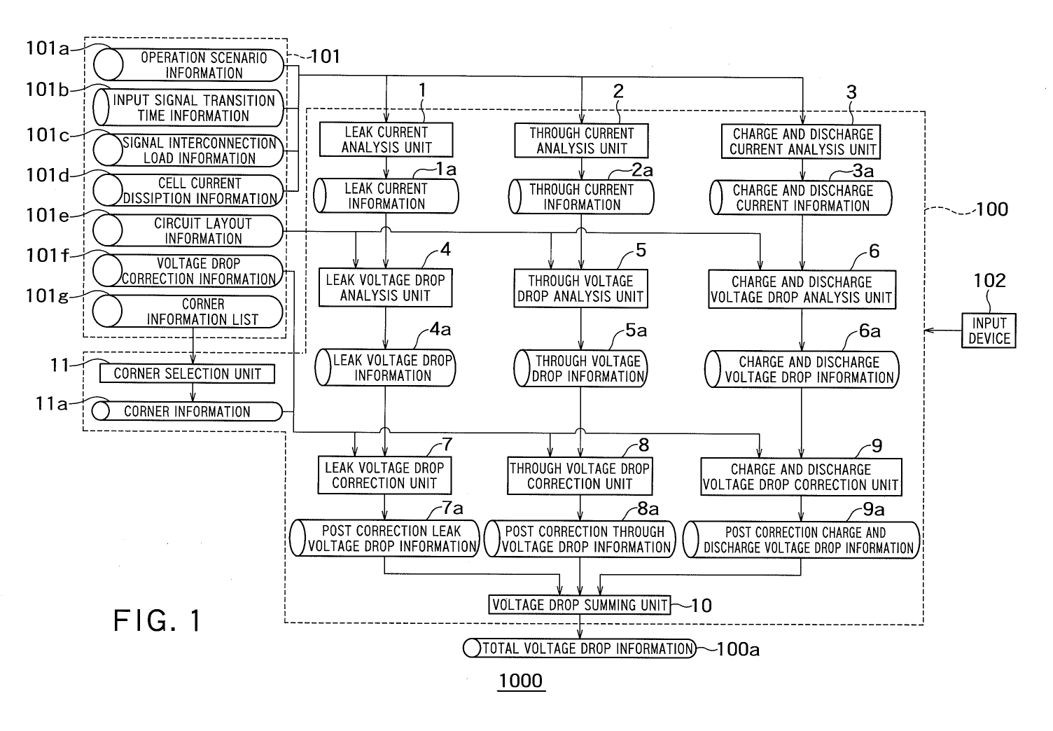

FIG. 1 is a diagram showing an example of a configuration of a system 1000 including a voltage drop analysis apparatus 100 according to an embodiment of the present invention.

As shown in FIG. 1, the system 1000 includes the voltage drop analysis apparatus 100, a database 101, and an input device 102.

The voltage drop analysis apparatus 100 is adapted to be supplied with operation scenario information 101a, input signal transition time information 101b, signal interconnection load information 101c, cell current dissipation information 101d, circuit layout information 101e, voltage drop correction information 101f, and a corner information list 101g stored in the database 101 in a file form.

The voltage drop analysis apparatus 100 is adapted to analyze voltage drops across elements which form a semiconductor integrated circuit of an analysis object on the basis of the information 101a to 101g in accordance with a command which is input by a user via the input device 102, and output total voltage drop information 100a.

Here, the operation scenario information 101a is information prescribing transitions of input signals and output signals of elements in the semiconductor integrated circuit. The operation scenario information 101a is described in a format such as, for example, VCD (Value Change Dump) or TWF (Timing Window File).

The input signal transition time information 101b is information prescribes transition time values required for input signals of respective elements in the semiconductor integrated circuit. The input signal transition time information 101b is described in a format such as, for example, the TWF (Timing Window File).

The signal interconnection load information 101c is information prescribing resistance values and capacitance values of signal interconnections connected to respective elements in the semiconductor integrated circuit. The signal interconnection load information 101c is described in a format such as, for example, SPEF (Standard Parasitic Extraction Format).

The cell current dissipation information 101d is a cell library required to calculate current dissipations of respective elements in the semiconductor integrated circuit. In other words, the cell current dissipation information 101d prescribes relations among the operation scenario information 101a, the input signal transition time information 101b, the signal interconnection load information 101c, and currents flowing through the elements. The cell current dissipation information 101d is described in a format such as, for example, Liberty or SPICE net list.

The circuit layout information 101e includes connection information of respective elements in the semiconductor integrated circuit, layout information of respective elements, and power supply interconnection information (such as shapes and line widths of power supply interconnections). The circuit layout information 101e is described in a format such as, for example, DEF (Design Exchange Format) or LEF (Library Exchange Format).

The corner information list 101g includes information of a transistor process corner, an interconnection process corner, a voltage corner, a temperature corner and the like, which is corner information 11a of voltage drop analysis objects. In other words, parameters which form the corner information 11a are, for example, a transistor process which prescribes the magnitude of the current flowing through a transistor, an interconnection process which prescribes the capacitance of the interconnection, voltage and temperature. In general, there is a plurality of corners of analysis objects. Therefore, the corner information list 101g enumerates a plurality of pieces of the corner information 11a.

The voltage drop correction information 101f is a library required to correct a voltage drop quantity according to the selected corner information 11a. The voltage drop correction information 101f prescribes relations between the corner information 11a and correction quantities of voltage drop information (leak voltage drop information 4a, through voltage drop information 5a and charge and discharge voltage drop information 6a). In other words, the voltage drop correction information 101f is a library which indicates relations between the parameters forming the corner information 11a and the voltage drop quantity.

The total voltage drop information 100a is a voltage drop analysis result of the voltage drop analysis apparatus 100. The total voltage drop information 100a represents the voltage drop quantity which is a total of voltage drop quantity caused by leak currents, through currents and charge and discharge currents of elements in the semiconductor integrated circuit of the analysis object.

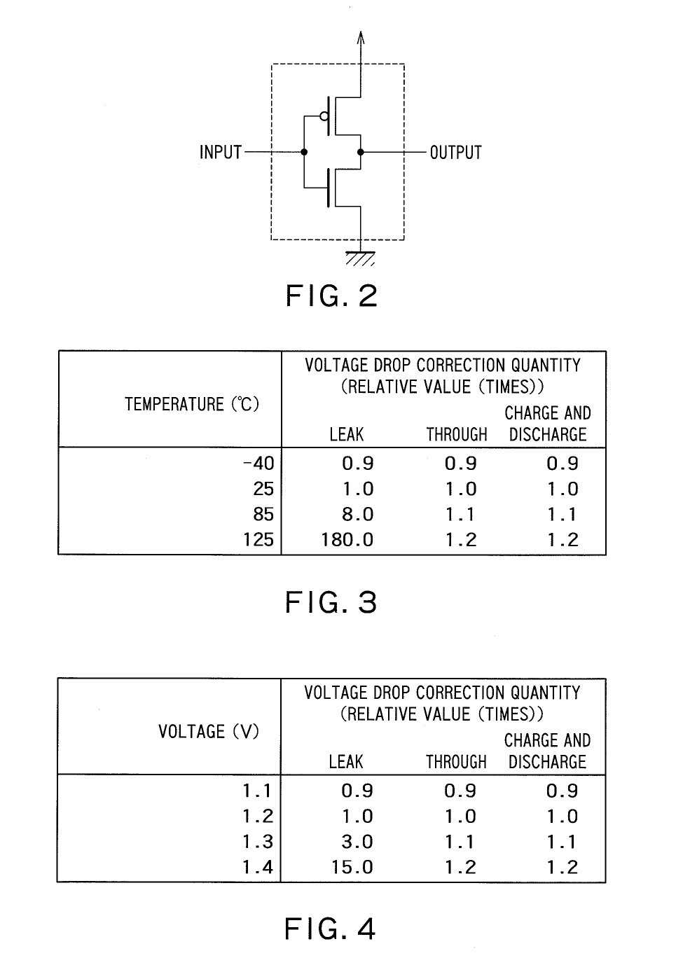

FIG. 2 is a circuit diagram showing an example of a circuit configuration of an element subject to voltage drop analysis made by the voltage drop analysis apparatus 100 shown in FIG. 1.

As shown in FIG. 2, the element is, for example, a CMOS transistor formed of a pMOS transistor and an nMOS transistor connected between a power supply and a ground in series and connected together at their gates. In this CMOS transistor, the gates are its input and a connection node of the pMOS transistor and the nMOS transistor is its output. For example, a cell such as a NAND circuit included in the semiconductor integrated circuit is formed by connecting a plurality of such elements.

Here, the leak current is, for example, a leak current which flows through the pMOS transistor and the nMOS transistor in the CMOS transistor (element) shown in FIG. 2. This leak current is let flow by the power supply voltage applied to the CMOS transistor regardless of the input signal.

The through current is, for example, a current which flows at the time of operation of the pMOS transistor and the nMOS transistor in the CMOS transistor (element) shown in FIG. 2 (when both the pMOS transistor and the nMOS transistor turn on during transition of the input signal).

The charge and discharge current is a current which flows through the pMOS transistor and the nMOS transistor when parasitic capacitance (not illustrated) connected to the output of the CMOS transistor (element) shown in FIG. 2 is charged or discharged.

In general, it is possible to calculate currents (the leak current, the through current, and the charge and discharge current) which flow through the element formed of the transistors on the basis of information concerning transition of the input signal and the output signal of the element, information concerning transition time required for the input signal of the element to make a transition, information concerning resistance values and capacitance values of signal interconnections connected to the element, and information (such as the Liberty or SPICE net list already described) concerning connection relations of the transistors included in the element, connection relations between transistors and interconnections, and transistor sizes.

As shown in FIG. 1, the voltage drop analysis apparatus 100 includes a leak current analysis unit 1, a through current analysis unit 2, a charge and discharge current analysis unit 3, a leak voltage drop analysis unit 4, a through voltage drop analysis unit 5, a charge and discharge voltage drop analysis unit 6, a leak voltage drop correction unit 7, a through voltage drop correction unit 8, a charge and discharge voltage drop correction unit 9, a voltage drop summing unit 10, and a corner selection unit 11.

The current analysis units (the leak current analysis unit 1, the through current analysis unit 2, and the charge and discharge current analysis unit 3) are adapted to analyze the current flowing through the element on the basis of the operation scenario information 101a, the input signal transition time information 101b, the signal interconnection load information 101c and the cell current dissipation information 101d and to output current information (leak current information 1a, through current information 2a and charge and discharge current information 3a) concerning currents which flow through the element.

In other words, the current analysis units analyze the leak current, the through current and the charge and discharge current, and output the current information concerning the leak current, the through current and the charge and discharge current which flow through the element.

The voltage drop analysis units (the leak voltage drop analysis unit 4, the through voltage drop analysis unit 5 and the charge and discharge voltage drop analysis unit 6) are adapted to analyze the voltage drop across the element on the basis of the circuit layout information 101e and the current information (the leak current information 1a, the through current information 2a and the charge and discharge current information 3a), and to output voltage drop information (the leak voltage drop information 4a, the through voltage drop information 5a and the charge and discharge voltage drop information 6a) concerning the voltage drop across the element.

In other words, the voltage drop analysis units analyze the voltage drop caused by the leak current, the through current and the charge and discharge current of the element, and output the voltage drop information concerning voltage drops caused by the leak current, the through current and the charge and discharge current of the element.

The corner selection unit 11 is adapted to select the corner information 11a of the element from the corner information list 101g which contains a plurality of pieces of the corner information 11a.

The voltage drop correction units (the leak voltage drop correction unit 7, the through voltage drop correction unit 8 and the charge and discharge voltage drop correction unit 9) output post correction voltage drop information (post correction leak voltage drop information 7a, post correction through voltage drop information 8a, and post correction charge and discharge voltage drop information 9a) obtained by correcting the voltage drop information on the basis of the voltage drop information (the leak voltage drop information 4a, the through voltage drop information 5a and the charge and discharge voltage drop information 6a), the selected corner information 11a, and the voltage drop correction information 101f.

In other words, the voltage drop correction units output respective post correction voltage drop information pieces obtained by correcting respective voltage drop information pieces caused by the leak current, the through current and the charge and discharge current of the element.

The voltage drop summing unit 10 sums the post correction voltage drop information pieces corresponding to the leak current, the through current and the charge and discharge current of the element, and outputs the sum value as the total voltage drop information 100a.

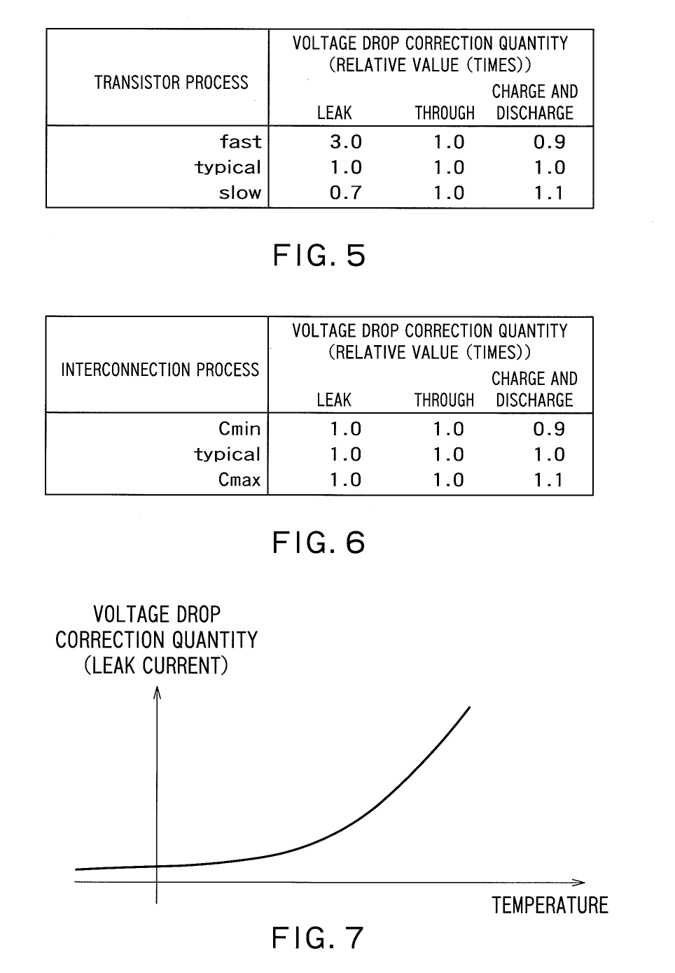

FIG. 3 is a diagram showing an example of the voltage drop correction information corresponding to a parameter (temperature) included in the corner information. FIG. 4 is a diagram showing an example of the voltage drop correction information corresponding to a parameter (voltage) included in the corner information. FIG. 5 is a diagram showing an example of the voltage drop correction information corresponding to a parameter (transistor process) included in the corner information. FIG. 6 is a diagram showing an example of the voltage drop correction information corresponding to a parameter (interconnection process) included in the corner information.

In FIG. 5, “transistor process (typical)” shows the case where the current which flows through a transistor has a typical value, “transistor process (fast)” shows the case where the current which flows through the transistor is large, and “transistor process (slow)” shows the case where the current which flows through the transistor is small.

In FIG. 6, “interconnection process (typical)” shows the case where the line width of a signal interconnection is typical and interconnection capacitance is typical, “interconnection process (Cmin)” shows the case where the line width of the signal interconnection is thin and the interconnection capacitance is small, and “interconnection process (Cmax)” shows the case where the line width of the signal interconnection is thick and the interconnection capacitance is large.

In the voltage drop correction information 101f, the voltage drop quantity is set equal to 1.0 under each of the following center conditions: the parameter (temperature) is 25° C. (FIG. 3); the parameter (voltage) is 1.2 V (FIG. 4); the parameter (transistor process) is typical (FIG. 5); and the parameter (interconnection process) is typical (FIG. 6) as shown in FIGS. 3 to 6. And in FIGS. 3 to 6, a relative value (times) of a voltage drop quantity under each of conditions deviated from the center conditions as compared with the voltage drop quantity under the center condition is shown.

For example, as shown in FIG. 3, the relative value of the leak voltage drop quantity is 0.9 times at the temperature of −40° C., 8.0 times at the temperature of 85° C., and 180.0 times at the temperature of 125° C., as compared with the leak voltage drop quantity at the temperature of 25° C.

In FIGS. 3 to 6, the voltage drop correction information 101f is described in the table form. However, the description method is not restricted to the table form, but the voltage drop correction information 101f may be described in other forms as described later.

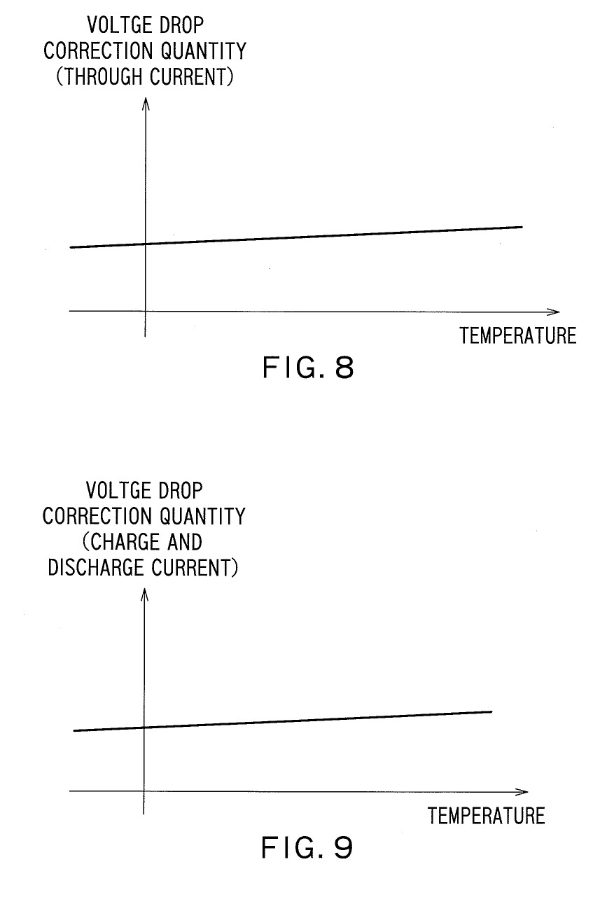

FIG. 7 is a diagram showing an example of a concept of the voltage drop correction information concerning the leak current. FIG. 8 is a diagram showing an example of a concept of the voltage drop correction information concerning the through current. FIG. 9 is a diagram showing an example of a concept of the voltage drop correction information concerning the charge and discharge current.

In FIGS. 7 to 9, the case where the parameter which forms the corner information is the temperature is exemplified.

If the parameter (temperature) which forms the corner information changes, the voltage drop correction quantity associated with the parameter also changes, as shown in FIGS. 7 to 9.

By the way, the voltage drop correction information 101f may be described in a form other than the table shown in FIGS. 3 to 6 as long as the relation between the parameter which forms the corner information 11a and the voltage drop quantity is shown. For example, the voltage drop correction information may be described in a form of functions which represent the curves shown in FIGS. 7 to 9.

An example of an operation of the voltage drop analysis conducted in the voltage drop analysis apparatus 100 having the configuration described heretofore will now be described.

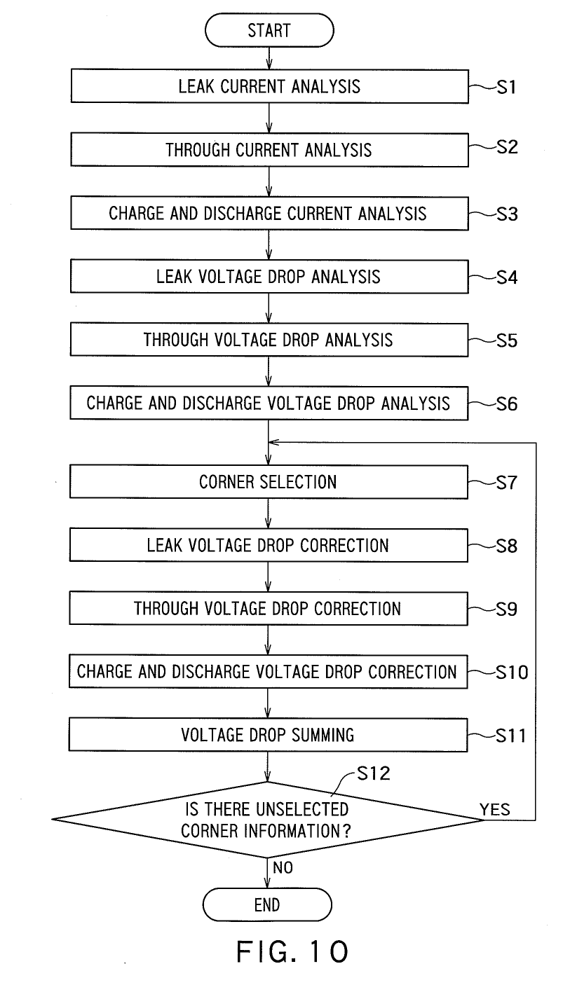

FIG. 10 is a flow chart showing an example of the operation of the voltage drop analysis of an element of analysis object conducted in the voltage drop analysis apparatus 100 shown in FIG. 1.

As shown in FIG. 10, at first, the leak current analysis unit 1 analyzes the leak current of each element of analysis object on the basis of the operation scenario information 101a, the input signal transition time information 101b, the signal interconnection load information 101c, and the cell current dissipation information 101d. And the leak current analysis unit 1 outputs the value of the leak current as the leak current information 1a (step S1).

By the way, the processing conducted by the leak current analysis unit 1 can be executed by using a typical power dissipation analysis tool.

Here, the leak current information 1a is a value of the leak current dissipated by each element in the circuit. For example, information having contents, such as that the leak current of a certain first element is 0.1 μA and the leak current of another second element is 0.2 μA, corresponds to the leak current information 1a.

Next, the through current analysis unit 2 analyzes the through current of each element of analysis object on the basis of the operation scenario information 101a, the input signal transition time information 101b, the signal interconnection load information 101c, and the cell current dissipation information 101d. And the through current analysis unit 2 outputs the value of the through current as the through current information 2a (step S2).

By the way, the processing conducted by the through current analysis unit 2 can be executed by using a typical power dissipation analysis tool.

Here, the through current information 2a is a value of the through current dissipated by each element in the circuit. For example, information having contents, such as that the through current of the first element is 10 μA and the through current of the second element is 20 μA, corresponds to the through current information 2a.

Then, the charge and discharge current analysis unit 3 analyzes the charge and discharge current of each element of analysis object on the basis of the operation scenario information 101a, the input signal transition time information 101b, the signal interconnection load information 101c, and the cell current dissipation information 101d. And the charge and discharge current analysis unit 3 outputs the value of the charge and discharge current as the charge and discharge current information 3a (step S3).

By the way, the processing conducted by the charge and discharge current analysis unit 3 can be executed by using a typical power dissipation analysis tool.

Here, the charge and discharge current information 3a is a value of the charge & discharge current dissipated by each element in the circuit. For example, information having contents, such as that the charge and discharge current of the first element is 10 μA and the charge and discharge current of the second element is 20 μA, corresponds to the charge and discharge current information 3a.

The steps S1 to S3 may be interchanged in execution order or executed in parallel.

In this way, the current analysis units 1 to 3 analyze currents which flow through the element on the basis of the operation scenario information 101a which prescribes transitions of an input signal and an output signal of the element, the input signal transition time information 101b which prescribes the transition time of the input signal of the element, the signal interconnection load information 101c which prescribes resistance values and capacitance values of signal interconnections connected to the element, and the cell current dissipation information 101d, and outputs the current information 1a to 3a concerning the currents flowing through the element.

Next, the leak voltage drop analysis unit 4 analyzes the voltage drop caused by the leak current of the element of analysis object on the basis of the leak current information 1a and the circuit layout information 101e, and outputs the leak voltage drop information 4a (step S4).

By the way, the processing conducted by the leak voltage drop analysis unit 4 can be executed by using a typical voltage drop analysis tool.

Here, the leak voltage drop information 4a is a value of a voltage drop caused by the leak current which is generated in each element in the semiconductor integrated circuit. For example, information having contents, such as that a voltage drop quantity caused by the leak current of a certain first element is 10 mV and a voltage drop quantity caused by the leak current of another second element is 8 mV, corresponds to the leak voltage drop information 4a.

Then, the through voltage drop analysis unit 5 analyzes the voltage drop caused by the through current of the element of analysis object on the basis of the through current information 2a and the circuit layout information 101e, and outputs the through voltage drop information 5a (step S5).

By the way, the processing conducted by the through voltage drop analysis unit 5 can be executed by using a typical voltage drop analysis tool.

Here, the through voltage drop information 5a is a value of a voltage drop caused by the through current which is generated in each element in the semiconductor integrated circuit. For example, information having contents, such as that a voltage drop quantity caused by the through current of a certain first element is 10 mV and a voltage drop quantity caused by the through current of another second element is 8 mV, corresponds to the through voltage drop information 5a.

Next, the charge and discharge voltage drop analysis unit 6 analyzes the voltage drop caused by the charge and discharge current of the element of analysis object on the basis of the charge and discharge current information 3a and the circuit layout information 101e, and outputs the charge and discharge voltage drop information 6a (step S6).

By the way, the processing conducted by the charge and discharge voltage drop analysis unit 6 can be executed by using a typical voltage drop analysis tool.

Here, the charge and discharge voltage drop information 6a is a value of a voltage drop caused by the charge and discharge current which is generated in each element in the semiconductor integrated circuit. For example, information having contents, such as that a voltage drop quantity caused by the charge and discharge current of a certain first element is 10 mV and a voltage drop quantity caused by the charge and discharge current of another second element is 8 mV, corresponds to the charge and discharge voltage drop information 6a.

The steps S4 to S6 may be interchanged in execution order or executed in parallel.

In this way, the voltage drop analysis units 4 to 6 analyze the voltage drops of the element on the basis of the circuit layout information 101e which includes information concerning connection of the element, arrangement (layout) of the element and the power supply interconnection connected to the element, and the current information 1a to 3a, and output the voltage drop information 4a to 6a concerning the voltage drops of the element.

Then, the corner selection unit 11 selects an unselected piece of corner information 11a from the corner information list 101g which contains a plurality of pieces of corner information 11a, and outputs the corner information 11a (step S7).

Then, the leak voltage drop correction unit 7 corrects the leak voltage drop information 4a on the basis of the selected corner information 11a and the voltage drop correction information 101f, and outputs the post correction leak voltage drop information 7a (step S8).

In the procedure of the correction, selection of a correction quantity from the voltage drop correction information, calculation of a total correction quantity, and application of the correction quantity are conducted in the cited order.

In the selection of a correction quantity, a correction quantity corresponding to the corner information 11a is selected from the voltage drop correction information 101f.

For example, if the selected corner information 11a indicates the temperature of 85° C., the voltage of 1.3 V, the transistor process “typical” and the interconnection process “Cmin” in FIGS. 3 to 6, the voltage drop correction quantities corresponding to the corner information is 8.0 in voltage drop correction quantity (temperature) (FIG. 3), 3.0 in voltage drop correction quantity (voltage) (FIG. 4), 1.0 in voltage drop correction quantity (transistor process) (FIG. 5), and 1.0 in voltage drop correction quantity (interconnection process) (FIG. 6).

In the calculation of a total correction quantity, a total correction quantity of one value is calculated. For example, a calculation equation of the total correction quantity is represented by Equation (1).

Total correction quantity={voltage drop correction quantity (temperature)−1}+{voltage drop correction quantity (voltage)−1}+{voltage drop correction quantity (transistor process)−1}+{voltage drop correction quantity (interconnection process)−1}+1 (1)

In the example already described, the total correction quantity based on Equation (1) is: total correction quantity={8.0−1}+{3.0−1}+{1.0−1}+{1.0−−1}+1=10.0.

By the way, Equation (1) differs depending upon the kind of the parameter which forms the corner information 11a.

In the application of the correction quantity, the voltage drop quantities of all elements are multiplied by the total correction quantity. For example, if the voltage drop quantity of a certain first element before the correction is 1 mV and the voltage drop quantity of another second element before the correction is 2 mV, the voltage drop quantity of the first element after the correction is 10 mV and the voltage drop quantity of the second element after the correction is 20 mV.

Here, the total correction quantity concerning the leak current is calculated. However, the total correction quantities concerning the through current and the charge and discharge current are also calculated in the same way.

Furthermore, the calculation method of the total correction quantity is not restricted to Equation (1). For example, a calculation equation of the total correction quantity which minimizes the error may be found and used by using a statistical technique such as the least square method.

Next, the through voltage drop correction unit 8 corrects the through voltage drop information 5a on the basis of the selected corner information 11a and the voltage drop correction information 101f, and outputs the post correction through voltage drop information 8a (step S9). The procedure of the correction is similar to that at the step S8 already described.

Then, the charge and discharge voltage drop correction unit 9 corrects the charge and discharge voltage drop information 6a on the basis of the selected corner information 11a and the voltage drop correction information 101f, and outputs the post correction charge and discharge voltage drop information 9a (step S10). The procedure of the correction is similar to that at the step S8 already described.

The steps S8 to S10 may be interchanged in execution order or executed in parallel.

In this way, the voltage drop correction units 7 to 9 output the post correction voltage drop information 7a to 9a obtained by correcting the voltage drop information 4a to 6a on the basis of the voltage drop information 4a to 6a, the selected corner information 11a, and the voltage drop correction information 101f which prescribes relations between the corner information 11a and correction quantities of the voltage drop information 4a to 6a.

Then, the voltage drop summing unit 10 outputs the total voltage drop information 100a obtained by summing up the voltage drops on the basis of the post correction leak voltage drop information 7a, the post correction through voltage drop information 8a, and the post correction charge and discharge voltage drop information 9a (step S11).

Summing up of voltage drops is achieved by simply adding up the post correction leak voltage drop information 7a, the post correction through voltage drop information 8a, and the post correction charge and discharge voltage drop information 9a.

For example, if the post correction leak voltage drop of a certain first element is 2 mV, the post correction through voltage drop of the first element is 1 mV, and the post correction charge and discharge voltage drop of the first element is 5 mV, the total voltage drop of the first element is 8 (=2+1+5) mV.

The total voltage drop information 100a is a result of the analysis conducted by the voltage drop analysis apparatus 100 with respect to the corner information 11a.

Then, the corner selection unit 11 determines whether there is corner information 11a which is not yet selected (step S12). If there is corner information 11a which is not yet selected, the processing returns to the step S7 for selecting the corner information 11a and an analysis corresponding to the next selected corner information 11a is made.

Owing to the flow described heretofore, the total voltage drop information 100a obtained by summing up voltage drops caused by the leak current, the through current and the charge and discharge current when the element of the analysis object is caused to operate under the conditions corresponding to the corner information 11a is acquired.

According to the voltage drop analysis method in the first embodiment, the power analysis and the voltage drop analysis are actually conducted only once between the step S1 where the leak current is analyzed and the step S6 where the voltage drop caused by the charge and discharge current is analyzed, as described heretofore.

And processing conducted for each of corner information written in the corner information list ranges from the step S8 where the leak voltage drop is corrected to the step S11 where the voltage drops are summed up.

Here, the processing time between the step S8 where the leak voltage drop is corrected to the step S11 where the voltage drops are summed up is negligibly small as compared with the processing time between the step S1 where the leak current is analyzed and the step S6 where the voltage drop caused by the charge and discharge current is analyzed.

As a matter of fact, therefore, the analysis of all corner information written in the corner information list is completed in an analysis time required to execute the processing between the step S1 where the leak current is analyzed and the step S6 where the voltage drop caused by the charge and discharge current is analyzed only once.

As a result, the execution time of the voltage drop analysis for the element of analysis object is shortened.

According to the voltage drop analysis apparatus in the present embodiment, the execution time of the voltage drop analysis can be shortened as described heretofore.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A voltage drop analysis apparatus which analyzes voltage drops of an element included in a semiconductor integrated circuit, the voltage drop analysis apparatus comprising:
a current analysis unit which analyzes currents flowing through the element on the basis of operation scenario information which prescribes transitions of an input signal and an output signal of the element, input signal transition time information which prescribes the transition time of the input signal of the element, signal interconnection load information which prescribes resistance values and capacitance values of signal interconnections connected to the element, and cell current dissipation information which prescribes relations among the operation scenario information, the input signal transition time information, the signal interconnection load information, and currents flowing through the element, and which outputs current information concerning currents flowing through the element;
a voltage drop analysis unit which analyzes voltage drops of the element on the basis of the current information and circuit layout information including information concerning connection of the element, arrangement of the element and power supply interconnection connected to the element, and which outputs voltage drop information concerning voltage drops of the element;
a corner selection unit which selects corner information of the element from a corner information list containing a plurality of pieces of corner information; and
a voltage drop correction unit which outputs post correction voltage drop information obtained by correcting the voltage drop information on the basis of the voltage drop information, the selected corner information, and the voltage drop correction information prescribing relations between the corner information and correction quantities of the voltage drop information.

2. The voltage drop analysis apparatus of claim 1, further comprising a voltage drop summing unit,
wherein the current analysis unit analyzes a leak current, a through current and a charge and discharge current, and outputs current information concerning the leak current, the through current and the charge and discharge current which flow through the element,
the voltage drop analysis unit analyzes a voltage drop caused by the leak current, the through current and the charge and discharge current of the element, and outputs a voltage drop information concerning voltage drops caused by the leak current, the through current and the charge and discharge current of the element,
the voltage drop correction unit outputs respective post correction voltage drop information pieces obtained by correcting respective voltage drop information pieces caused by the leak current, the through current and the charge and discharge current of the element, and
the voltage drop summing unit sums the post correction voltage drop information pieces corresponding to the leak current, the through current and the charge and discharge current of the element, and outputs the sum value as the total voltage drop information.

3. The voltage drop analysis apparatus of claim 1, wherein parameters form the corner information, the parameters being a transistor process which prescribes the magnitude of the current flowing through a transistor, an interconnection process which prescribes the capacitance of the interconnection, voltage and temperature.

4. The voltage drop analysis apparatus of claim 2, wherein parameters form the corner information, the parameters being a transistor process which prescribes the magnitude of the current flowing through a transistor, an interconnection process which prescribes the capacitance of the interconnection, voltage and temperature.

5. The voltage drop analysis apparatus of claim 1, wherein the information concerning the power supply interconnection includes shapes and line widths of power supply interconnections.

6. The voltage drop analysis apparatus of claim 2, wherein the information concerning the power supply interconnection includes shapes and line widths of power supply interconnections.

7. The voltage drop analysis apparatus of claim 3, wherein the information concerning the power supply interconnection includes shapes and line widths of power supply interconnections.

8. The voltage drop analysis apparatus of claim 4, wherein the information concerning the power supply interconnection includes shapes and line widths of power supply interconnections.

9. The voltage drop analysis apparatus of claim 1, wherein the element is a CMOS transistor.

10. A voltage drop analysis method which analyzes voltage drops of an element included in a semiconductor integrated circuit, the voltage drop analysis method comprising:
analyzing currents flowing through the element by a current analysis unit on the basis of operation scenario information which prescribes transitions of an input signal and an output signal of the element, input signal transition time information which prescribes the transition time of the input signal of the element, signal interconnection load information which prescribes resistance values and capacitance values of signal interconnections connected to the element, and cell current dissipation information which prescribes relations among the operation scenario information, the input signal transition time information, the signal interconnection load information, and currents flowing through the element, and outputting current information concerning currents flowing through the element by the current analysis unit;
analyzing voltage drops of the element by a voltage drop analysis unit on the basis of the current information and circuit layout information including information concerning connection of the element, arrangement of the element and power supply interconnection connected to the element, and which outputting voltage drop information concerning voltage drops of the element by the voltage drop analysis unit;
selecting corner information of the element from a corner information list containing a plurality of pieces of corner information by a corner selection unit; and
outputting post correction voltage drop information obtained by correcting the voltage drop information by a voltage drop correction unit on the basis of the voltage drop information, the selected corner information, and the voltage drop correction information prescribing relations between the corner information and correction quantities of the voltage drop information.

11. The voltage drop analysis method of claim 10, further comprising a voltage drop summing unit,
wherein the current analysis unit analyzes a leak current, a through current and a charge and discharge current, and outputs current information concerning the leak current, the through current and the charge and discharge current which flow through the element,
the voltage drop analysis unit analyzes a voltage drop caused by the leak current, the through current and the charge and discharge current of the element, and outputs a voltage drop information concerning voltage drops caused by the leak current, the through current and the charge and discharge current of the element,
the voltage drop correction unit outputs respective post correction voltage drop information pieces obtained by correcting respective voltage drop information pieces caused by the leak current, the through current and the charge and discharge current of the element, and
the voltage drop summing unit sums the post correction voltage drop information pieces corresponding to the leak current, the through current and the charge and discharge current of the element, and outputs the sum value as the total voltage drop information.

12. The voltage drop analysis method of claim 10, wherein parameters form the corner information, the parameters being a transistor process which prescribes the magnitude of the current flowing through a transistor, an interconnection process which prescribes the capacitance of the interconnection, voltage and temperature.

13. The voltage drop analysis method of claim 11, wherein parameters form the corner information, the parameters being a transistor process which prescribes the magnitude of the current flowing through a transistor, an interconnection process which prescribes the capacitance of the interconnection, voltage and temperature.

14. The voltage drop analysis method of claim 10, wherein the information concerning the power supply interconnection includes shapes and line widths of power supply interconnections.

15. The voltage drop analysis method of claim 11, wherein the information concerning the power supply interconnection includes shapes and line widths of power supply interconnections.

16. The voltage drop analysis method of claim 12, wherein the information concerning the power supply interconnection includes shapes and line widths of power supply interconnections.

17. The voltage drop analysis method of claim 13, wherein the information concerning the power supply interconnection includes shapes and line widths of power supply interconnections.

18. The voltage drop analysis method of claim 10, wherein the element is a CMOS transistor.

19. A system comprising:
an input device which inputs a command given by a user; and
a voltage drop analysis apparatus which analyzes voltage drops of an element included in a semiconductor integrated circuit of analysis object and which outputs total voltage drop information, in response to the command,
wherein the voltage drop analysis apparatus comprises:
a current analysis unit which analyzes currents flowing through the element on the basis of operation scenario information which prescribes transitions of an input signal and an output signal of the element, input signal transition time information which prescribes the transition time of the input signal of the element, signal interconnection load information which prescribes resistance values and capacitance values of signal interconnections connected to the element, and cell current dissipation information which prescribes relations among the operation scenario information, the input signal transition time information, the signal interconnection load information, and currents flowing through the element, and which outputs current information concerning currents flowing through the element;
a voltage drop analysis unit which analyzes voltage drops of the element on the basis of the current information and circuit layout information including information concerning connection of the element, arrangement of the element and power supply interconnection connected to the element, and which outputs voltage drop information concerning voltage drops of the element;
a corner selection unit which selects corner information of the element from a corner information list containing a plurality of pieces of corner information; and
a voltage drop correction unit which outputs post correction voltage drop information obtained by correcting the voltage drop information on the basis of the voltage drop information, the selected corner information, and the voltage drop correction information prescribing relations between the corner information and correction quantities of the voltage drop information.

20. The system of claim 19, further comprising a voltage drop summing unit,
wherein the current analysis unit analyzes a leak current, a through current and a charge and discharge current, and outputs current information concerning the leak current, the through current and the charge and discharge current which flow through the element,
the voltage drop analysis unit analyzes a voltage drop caused by the leak current, the through current and the charge and discharge current of the element, and outputs a voltage drop information concerning voltage drops caused by the leak current, the through current and the charge and discharge current of the element,
the voltage drop correction unit outputs respective post correction voltage drop information pieces obtained by correcting respective voltage drop information pieces caused by the leak current, the through current and the charge and discharge current of the element, and
the voltage drop summing unit sums the post correction voltage drop information pieces corresponding to the leak current, the through current and the charge and discharge current of the element, and outputs the sum value as the total voltage drop information.
